(19) United States
(12) Patent Application Publication
(10) Pub. No.: US 2017/0315218 A1
(43) Pub. Date: Nov. 2, 2017

(54) PHOTO DETECTION DEVICE AND LIDAR DEVICE

(71) Applicant: Kabushiki Kaisha Toshiba, Tokyo (JP)

(72) Inventors: Toshiya YONEHARA, Kawasaki (JP); Kazuhiro SUZUKI, Tokyo (JP)

(73) Assignee: Kabushiki Kaisha Toshiba, Tokyo (JP)

(21) Appl. No.: 15/455,327

(22) Filed: Mar. 10, 2017

(30) Foreign Application Priority Data
Apr. 28, 2016 (JP) 2016-090427

(51) Int. Cl. G01S 7/481; H01L 31/028; H01L 31/0232; H01L 31/107; G01S 17/08

(52) U.S. Cl. CPC G01S 7/4816; H01L 31/107; G01S 17/08; H01L 31/02327; H01L 31/028

(57) ABSTRACT

In one embodiment, a photo detection device is provided with a first photo detector having a first semiconductor layer with a first light receiving surface, a second photo detector having a second semiconductor layer with a second light receiving surface, and a substrate which is arranged on the first light receiving surface of the first semiconductor layer and the second light receiving surface of the second semiconductor layer and transmits light. A thickness of the first semiconductor layer and a thickness of the second semiconductor layer are different from each other.

### CROSS-REFERENCE TO RELATED APPLICATION

This application is based upon and claims the benefit of priority from the prior Japanese Patent Application No. 2016-090427, filed on Apr. 28, 2016, the entire contents of which are incorporated herein by reference.

### FIELD

Embodiments described herein relate generally to a photo detection device and a LIDAR (Laser Imaging Detection and Ranging) device.

### BACKGROUND

A photo detector using an avalanche photo diode (APD) detects weak light, and amplifies a signal to be outputted. When an APD is made of silicon (Si), light sensitivity characteristic of the photo detector largely depends on absorption characteristic of silicon. The APD made of silicon most absorbs light with a wavelength of 400-600 nm. The APD hardly has sensitivity to light of a near infra-red wavelength band. In order to improve sensitivity of light in a near infra-red wavelength band, it is known to make a depletion layer very thick, such as several ten μm. However, a drive voltage of the photo detector might become very high, such as several hundred volts.

Accordingly, in a photo detector using silicon, a structure to confine light inside a photo detector has been considered, in order to enhance detection efficiency of light in a near infra-red wavelength band.

### BRIEF DESCRIPTION OF THE DRAWINGS

FIG. 1 is a diagram showing a structure of a photo detector.

FIG. 2A is a diagram showing a photo detector of a comparative example.

FIG. 2B is a diagram showing a light absorption efficiency of the photo detector.

FIG. 2C is a diagram showing a photo detector of the comparative example.

FIG. 3A is a diagram showing a photo detection device in a first embodiment.

FIG. 3B is a sectional view of the first embodiment photo detection device.

FIG. 3C is a diagram showing an equivalent circuit of the first embodiment photo detection device.

FIG. 4A is a diagram showing the relation between a light absorption efficiency of the photo detection device in the first embodiment and a wavelength of light.

FIG. 4B is a diagram showing the relation between a light absorption efficiency of the photo detection device in the first embodiment and a wavelength of light.

FIG. 4C is a diagram showing the relation between a light absorption efficiency and a thickness of the semiconductor layer in the first embodiment

FIG. 4D is a diagram showing the relation between a thickness difference of the semiconductor layer in the first embodiment and a wavelength of light.

FIG. 5A is a diagram showing a photo detection device in a second embodiment.

FIG. 5B is a diagram showing an light absorption efficiency of the photo detection device in the second embodiment.

FIG. 5C is a diagram showing the relation between a light absorption efficiency of the second embodiment photo detection device and a thickness of an optical property adjustment layer

FIG. 6A is a diagram showing the relation between a light absorption efficiency of the photo detection device in the second embodiment and a wavelength of light.

FIG. 6B is a diagram showing the relation between a light absorption efficiency of the photo detection device in the second embodiment and a thickness of an optical property adjustment layer.

FIG. 6C is a diagram showing the relation between a light absorption efficiency of the photo detection device in the second embodiment and a wavelength of light.

FIG. 6D is a diagram showing the relation between a light absorption efficiency of the photo detection device in the second embodiment and a wavelength of light.

FIG. 7A is a diagram showing the relation between a cycle of a thickness in the optical property adjustment layer and a wavelength of light.

FIG. 7B is a diagram showing the relation between a cycle of a thickness in the optical property adjustment layer and wavelength of light.

FIG. 8A is a diagram showing a photo detection device in a third embodiment.

FIG. 8B is a diagram showing the relation between a light absorption efficiency of the photo detection device in the third embodiment and a wavelength of light.

FIG. 8C is a diagram showing the photo detection device in the third embodiment.

FIG. 9A is a diagram showing a photo detection device in a fourth embodiment.

FIG. 9B is a diagram showing the relation between a light absorption efficiency of the photo detection device in the fourth embodiment and a wavelength of light.

FIG. 9C is a diagram showing the relation between a light absorption efficiency of the photo detection device in the fourth embodiment and a wavelength of light.

FIG. 10 is a diagram showing a photo detection device in a fifth embodiment.

FIG. 11A is a diagram showing a manufacturing method of a photo detector.

FIG. 11B is a diagram showing the manufacturing method of a photo detector.

FIG. 11C is a diagram showing the manufacturing method of a photo detector.

FIG. 11D is a diagram showing the manufacturing method of a photo detector.

FIG. 12A is a diagram showing a manufacturing method of a photo detection device.

FIG. 12B is a diagram showing the manufacturing method of a photo detection device.

FIG. 12C is a diagram showing the manufacturing method of a photo detection device.

FIG. 12D is a diagram showing the manufacturing method of a photo detection device.

FIG. 12E is a diagram showing the manufacturing method of a photo detection device.

FIG. 13A is a diagram showing a manufacturing method of a mold.

FIG. 13B is a diagram showing the manufacturing method of a mold.

FIG. 13C is a diagram showing the manufacturing method of a mold.

FIG. 13D is a diagram showing the manufacturing method of a mold.

FIG. 14A is a diagram showing a configuration of a measuring system

FIG. 14B is a diagram showing a configuration of a measuring system

FIG. 14C is a diagram showing a configuration of a measuring system

FIG. 15 is a diagram showing a LIDAR device.

### DETAILED DESCRIPTION

According to one embodiment, a photo detection device is provided with a first photo detector having a first semiconductor layer with a first light receiving surface, a second photo detector having a second semiconductor layer with a second light receiving surface, and a substrate which is arranged on the first light receiving surface of the first semiconductor layer and the second light receiving surface of the second semiconductor layer and transmits light. A thickness of the first semiconductor layer and a thickness of the second semiconductor layer are different from each other.

Hereinafter, further embodiments will be described with reference to the drawings. Ones with the same symbols show the similar ones. In addition, the drawings are schematic or conceptual, and accordingly, the relation between a thickness and a width in each portion, and a ratio coefficient of sizes between portions are not necessarily identical to those of the actual ones. In addition, even when the same portions are shown, the dimensions and the ratio coefficients thereof may be shown differently depending on the drawings.

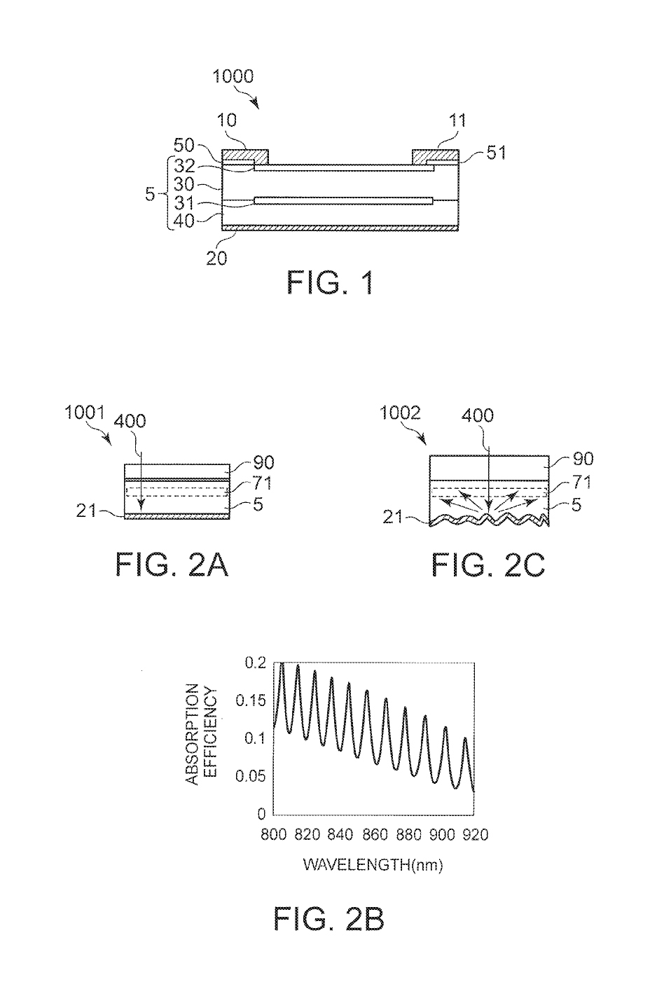

FIG. 1 is a diagram showing a photo detector 1000. The photo detector 1000 is composed of a type semiconductor layer 32, a p⁻ type semiconductor layer 30, a p⁺ type semiconductor layer 31, an n type semiconductor layer 40, first electrodes 10, 11, and a second electrode 20.

The p⁺ type semiconductor layer 32, the p⁻ type semiconductor layer 30, the p⁺ type semiconductor layer 31, and the n type semiconductor layer 40 are collectively called a semiconductor layer 5. The semiconductor layer 5 is composed of the p⁺ type semiconductor layer 32, the p⁻ type semiconductor layer 30, the p⁺ type semiconductor layer 31, and the n type semiconductor layer 40, in the order from the p⁺ type semiconductor layer 32 at a light receiving surface side.

In the photo detector 1000, the semiconductor layer 5 is composed of Si (silicon), for example. It is more preferable to select Si as the material of the semiconductor layer 5, because the manufacturing cost is not expensive.

The insulating layers 50, 51 are provided at the same side as the p⁺ type semiconductor layer 32 serving as a light receiving surface of the photo detector 1000.

The first electrodes 10, 11 are provided at the same side as the p⁺ type semiconductor layer 32 serving as the light receiving surface of the photo detector 1000. The first electrode 10 is provided so as to cover a part of the p⁺ type semiconductor layer 32 and the insulating layer 50. The first electrode 11 is provided so as to cover a part of the p⁺ type semiconductor layer 32 and the insulating layer 51.

The second electrode 20 is provided on the semiconductor layer 5 at a side opposite to the p⁺ type semiconductor layer 32 serving as the light receiving surface of the photo detector 1000.

Light is incident from the p⁺ type semiconductor layer 32 serving as the light receiving surface of the photo detector 1000. The incident light is absorbed by a depletion layer formed of the p type semiconductor layer 30, the p⁺ type semiconductor layer 31, and the n type semiconductor layer 40. The incident light is converted into electron-hole pairs in the depletion layer.

When a voltage serving as a reverse bias is applied between the first electrodes 10, 11 and the second electrode 20, electrons of the electron-hole pairs flow in the direction of the n type semiconductor layer 40. Holes of the electron-hole pairs flow in the direction of the p⁺ type semiconductor layer 32. At this time, if the voltage between the first electrodes 10, 11 and the second electrode 20 is increased, the flowing speed of the electrons and holes are accelerated in the depletion layer. Particularly, in the type semiconductor layer 31, electrons come in collision with atoms in the p⁻ type semiconductor layer 30, to generate new electron-hole pairs. This phenomenon is called avalanche amplification. The avalanche amplification is a reaction which occurs in chains. The avalanche amplification is generated, and thereby the photo detector 1000 can detect weak light.

A distance d between the first electrodes 10, 11 and the second electrode 20 is 1-15 μm, for example. If the distance d is smaller than 1 μm, a region of the depletion layer becomes small. Accordingly, detection efficiency and amplification factor of light of the photo detector 1000 become low. If the distance d is larger than 15 μm, a high voltage is to be applied as the voltage between the first electrodes 10, 11 and the second electrode 20. In addition, light absorption at outside the depletion layer increases, to cause reduction of the detection efficiency of light.

In the photo detector 1000, a dead time when light cannot be detected is generated after the avalanche amplification has occurred. The dead time of the photo detector 1000 is made short, and thereby the photo detector 1000 can detect light efficiently. In order to make the dead time of the photo detector 1000 short, it is necessary to promptly take out the electrons and holes existing inside the photo detector 1000 to the outside. At this time, speed at which the electrons and holes are taken out to the outside of the photo detector 1000 is determined by a capacitance C of the photo detector 1000. The capacitance C depends on an area S of the p⁺ type semiconductor layer 32 serving as the light receiving surface. The smaller the area S of the p⁺ type semiconductor layer 32 serving as the light receiving surface is, the smaller the capacitance C of the photo detector 1000 becomes. The smaller the area S of the p⁺ type semiconductor layer 32 serving as the light receiving surface is, the more promptly the electrons and holes existing inside the photo detector 1000 can be taken out to the outside.

Accordingly, it is preferable that the area S of the p⁺ type semiconductor layer 32 serving as the light receiving surface is not more than 100 μm×100 μm. On the other hand, when the area S of the p⁺ type semiconductor layer 32 serving as the light receiving surface is too small, the detection sensitivity of the photo detector 1000 is decreased. In order to make compatible the reduction of the dead time with the detection sensitivity of light, the area S of the p⁺ type semiconductor layer 32 serving as the light receiving surface is 25 μm×25 μm, for example.

### Comparative Example

FIG. 2A is a diagram showing a photo detector 1001, FIG. 2B is a diagram showing a light absorption efficiency of the photo detector 1001, and FIG. 2C is a diagram showing a photo detector 1002.

In FIG. 2A, the photo detector 1001 is composed by further having a substrate 90 and a reflective material 21 in addition to the above-described semiconductor layer 5.

The same symbols are given to the same portions as in FIG. 1, and the description thereof will be omitted. In addition, regarding the semiconductor layer 5, the p⁺ type semiconductor layer 32, the p⁻ type semiconductor layer 30, the p⁺ type semiconductor layer 31, and the n type semiconductor layer 40 are omitted in the drawings, and they are simply shown as the semiconductor layer 5.

The substrate 90 is provided on the p⁺ type semiconductor layer 32 that is a light receiving surface of the semiconductor layer 5. A light 400 passes through the substrate 90, and is incident on the p⁺ type semiconductor layer 32 that is the light receiving surface of the semiconductor layer 5. A part of the light 400 is absorbed by a depletion layer 71 inside the semiconductor layer 5. The light 400 which has not been absorbed in the depletion layer 71 is reflected by the reflective material 21, and enters the depletion layer 71 again, and is absorbed by the depletion layer 71, When the reflective material 21 is provided, the reflectance can be increased more, and accordingly the absorption efficiency can be increased more In addition, a refractive index of the semiconductor layer 5 is different from that of the outside. For the reason, even when the reflective material 21 is not provided, the light 400 is reflected by an interface of the semiconductor layer 5 and the outside. Accordingly, the reflective material 21 may not be provided.

FIG. 2B shows the relation between a light absorption efficiency of the depletion layer 71 in the photo detector 1001 and a wavelength of light.

FIG. 2B is calculated by simulation. The condition of simulation was that the substrate 90 is made of glass of a thickness of 0.3 mm, the semiconductor layer 5 is made of Si and a thickness thereof is 8 μm, the reflective material 21 is made of Al (aluminum) of a thickness of 150 nm, the depletion layer 71 exists at a position 0.5 μm-2.5 μm distant from the interface of the substrate 90 and the semiconductor layer 5, and a thickness of the depletion layer 71 is 2 μm.

The light absorption efficiency of the photo detector 1001 has large wavelength dependency due to the optical interference effect. When the wavelength dependency of the photo detector 1001 is large, the detection efficiency of light of the photo detector 1001 may largely be varied depending on the wavelength of incident light.

In the photo detector 1002 shown in FIG. 2C, the semiconductor layer 5 at a side opposite to the substrate 90 side has a concave/convex shape, and the surface thereof is covered with the reflective material 21.

The light 400 incident on the photo detector 1002 is scattered by the concavity/convexity of the semiconductor layer 5.

Accordingly, the reduction of the wavelength dependency of the light 400 due to the optical interference is expected. However, in the photo detector 1002, since a concave/convex structure is provided in the semiconductor layer 5, defects are easily generated in the semiconductor layer 5. Accordingly, in the photo detector 1002, electrical characteristic deterioration such as the increase of a dark current is generated.

### First Embodiment

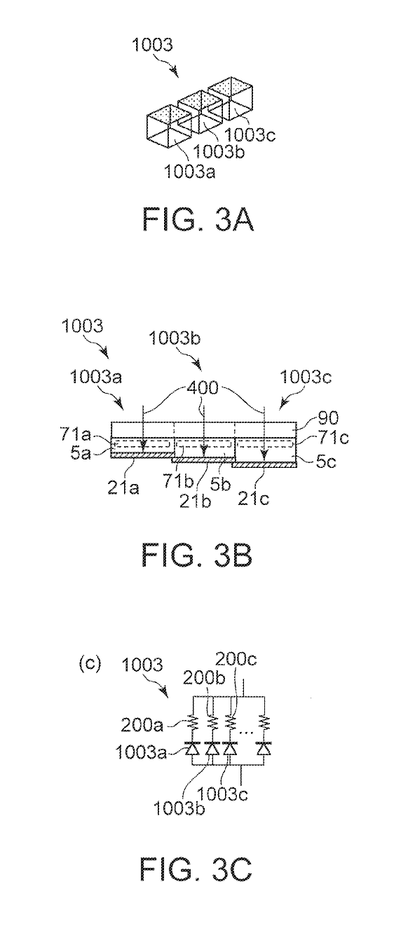

FIG. 3A is a schematic diagram of a photo detection device 1003, FIG. 3B is a sectional view of the photo detection device 1003, and FIG. 3C is a diagram showing an equivalent circuit of the photo detection device 1003.

In FIG. 3A, the photo detection device 1003 is composed of a photo detector 1003a, a photo detector 1003b, and a photo detector 1003c. In the photo detection device 1003, the photo detector 1003a, the photo detector 1003b, and the photo detector 1003c are arranged as shown in FIG. 3A, for example. In addition, in the photo detection device 1003, the photo detector 1003a, the photo detector 1003b, and the photo detector 1003c may not be arranged in a line as shown in FIG. 3A, and the photo detector 1003a, the photo detector 1003b, and the photo detector 1003c may be arranged at separate positions to each other.

In FIG. 3B, semiconductor layers 5a, 5b, 5c are the same as the semiconductor layer 5 as described above. Reflective materials 21a, 21b, 21c are the same as the reflective material 21 as described above.

The photo detector (first photo detector) 1003a is composed of the substrate 90, the semiconductor layer 5a, and the reflective material (first reflective material) 21a. The substrate 90 is provided on the p⁺ type semiconductor layer 32 side of the semiconductor layer 5a. The p⁺ type semiconductor layer 32 of the photo detector 1003a forms a light receiving surface (first light receiving surface). The reflective material 21a is provided on a side opposite to the light receiving surface side of the semiconductor layer 5a. A depletion layer 71a exists inside the semiconductor layer 5a.

The photo detector (second photo detector) 1003b is composed of the substrate 90, the semiconductor layer 5b, and the reflective material (second reflective material) 21b. The substrate 90 is provided on the p⁺ type semiconductor layer 32 side of the semiconductor layer 5b. The p⁺ type semiconductor layer 32 of the photo detector 1003b forms a light receiving surface (second light receiving surface). The reflective material 21b is provided on a side opposite to the light receiving surface side of the semiconductor layer 5b. A depletion layer 71b exists inside the semiconductor layer 5b.

The photo detector 1003c (third photo detector) is composed of the substrate 90, the semiconductor layer 5c, and the reflective material 21c. The substrate 90 is provided on the p⁺ type semiconductor layer 32 side of the semiconductor layer 5c, The p⁺ type semiconductor layer 32 of the photo detector 1003c forms a light receiving surface. The reflective material 21c is provided on a side opposite to the p⁺ type semiconductor layer 32 side of the semiconductor layer 5c. A depletion layer 71c exists inside the semiconductor layer 5c.

Each of the semiconductor layers 5a, 5b, 5c is composed of the p type semiconductor layer and the n type semiconductor layer in this order from the p⁺ type semiconductor layer 32 side toward a direction opposite to the p⁺ type semiconductor layer 32 side.

Each of the semiconductor layers 5a, 5b, 5c is composed of the p⁺ type semiconductor layer 32, the p⁻ type semiconductor layer 30, the p⁺ type semiconductor layer 31, the n type semiconductor layer 40 in this order, from the p⁺ type semiconductor layer 32 side toward a direction opposite to the p⁺ type semiconductor layer 32 side. In each of the semiconductor layers 5a, 5b, 5c, the p⁺ type semiconductor layers 31, 32 may not be provided, and may be a laminated structure of a p type semiconductor and an n type semiconductor. Each of The semiconductor layers 5a, 5b, 5c may be composed of the n type semiconductor layer and the p type semiconductor layer in this order, from the p⁺ type semiconductor layer 32 side toward a direction opposite to the p⁺ type semiconductor layer 32 side.

Each of the semiconductor layers 5a, 5b, 5c may be composed of the n⁺ type semiconductor layer, the n⁻ type semiconductor layer, the n⁺ type semiconductor layer, the p type semiconductor layer in this order, from the p⁺ type semiconductor layer 32 side toward a direction opposite to the p⁺ type semiconductor layer 32 side.

Each of the semiconductor layers 5a, 5b, 5c is composed of Si (silicon).

It is supposed that a wavelength of light incident on the p⁺ type semiconductor layer 32 that is the light receiving surface is not less than 750 nm and not more than 1000 nm.

Respective areas of the light receiving surface (first light receiving surface) of the photo detector 1003a, the light receiving surface (second light receiving surface) of the photo detector 1003b, the light receiving surface of the photo detector 1003c may be different from each other.

The substrate 90 may be commonly used in the photo detector 1003a, the photo detector 1003b, and the photo detector 1003c.

Between the substrate 90 and the semiconductor layer 5a, between the substrate 90 and the semiconductor layer 5b, and between the substrate 90 and the semiconductor layer 5c, passivation layers or adhesive layers not shown may be provided respectively. The passivation layer is provided for protecting each of the semiconductor layers 5a, 5b, 5c. The passivation layer is a silicon oxide film (SiO₂). The adhesive layer is provided for improving adhesiveness of the substrate 90 with each of the semiconductor layers 5a, 5b, 5c, or adhesiveness of the substrate 90 with the passivation layer.

In the photo detection device 1003, a thickness of the semiconductor layer 5a of the photo detector 1003a, a thickness of the semiconductor layer 5b of the photo detector 1003b, and a thickness of the semiconductor layer 5c of the photo detector 1003c are different from each other. The thickness of the semiconductor layer 5a of the photo detector 1003a, the thickness of the semiconductor layer 5b of the photo detector 1003b, and the thickness of the semiconductor layer 5c of the photo detector 1003c are different from each other, and thereby absorption efficiencies of light in the respective wavelengths of light of the photo detector 1003a, the photo detector 1003b, and the photo detector 1003c are different. For the reason, the wavelength dependency of light of the light absorption efficiency of the photo detection device 1003 can be made small.

As shown in FIG. 3C, the photo detection device 1003 contains quench resistors 200a, 200b, 200c. The quench resistor 200a is contained in the photo detector 1003a, and is connected in series with the photo detector 1003a. The quench resistor 200b is contained in the photo detector 1003b, and is connected in series with the photo detector 1003b. The quench resistor 200c is contained in the photo detector 1003c, and is connected in series with the photo detector 1003c.

Each of the quench resistors 200a, 200b, 200c is provided for adjusting a speed at the time of drawing a current generated by avalanche amplification in the corresponding one of the photo detectors 1003a, 1003b, 1003c. The quench resistor 200a of the photo detector 1003a, the quench resistor 200b of the photo detector 1003b, and the quench resistor 200c of the photo detector 1003c are connected in parallel with each other. Quench resistors are contained in respective photo detectors of a photo detection device described later. Also, in the photo detection device described later, the quench resistors of the respective photo detectors are connected in parallel with each other.

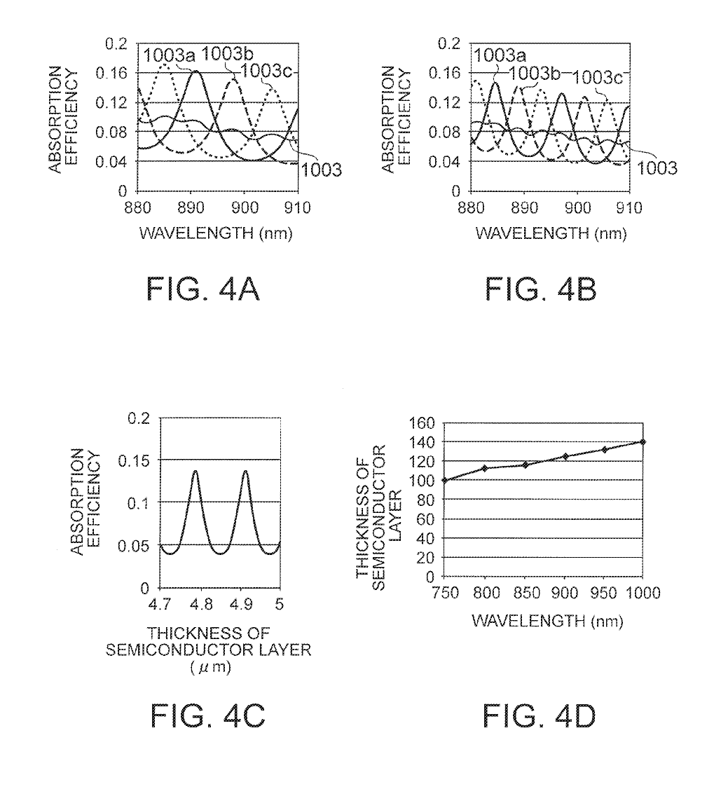

FIG. 4A is a diagram showing the relation between a light absorption efficiency and a wavelength of light of the photo detection device 1003, FIG. 4B is a diagram showing the relation between a light absorption efficiency and a wavelength of light of the photo detection device 1003, FIG. 4C is a diagram showing the relation between a light absorption efficiency and a thickness of the semiconductor layer 5a of the photo detector 1003a, and FIG. 4D is a diagram showing the relation between a thickness difference of the semiconductor layer 5a and a wavelength of light when a light absorption efficiency becomes periodical are respectively shown.

FIG. 4A is calculated by simulation. The condition of simulation was that the substrate 90 is made of glass of a thickness of 0.3 mm, each of the semiconductor layers 5a, 5b, 5c is made of Si (silicon), each of the reflective materials 21a, 21b, 21c is made of Al (aluminum) of a thickness of 150 nm.

A thickness of each of the depletion layers 71a, 71b, 71c is 2 μm. The depletion layers 71a, 71b, 71c respectively exist in the semiconductor layers 5a, 5b, 5c which are 0.5 μm-2.5 μm distant from the substrate 90.

A thickness of the semiconductor layer 5a of the photo detector 1003a is 4.7 μm, a thickness of the semiconductor layer 5b of the photo detector 1003b is 4.742 μm, and a thickness of the semiconductor layer 5c of the photo detector 1003c is 4.786 μm.

In FIG. 4A, a light absorption efficiency of the photo detector 1003a, a light absorption efficiency of the photo detector 1003b, and a light absorption efficiency of the photo detector 1003c are respectively shown.

Each of the light absorption efficiency of the photo detector 1003a, the light absorption efficiency of the photo detector 1003b, and the light absorption efficiency of the photo detector 1003c depends on a wavelength of light.

Further, in FIG. 4A, an average light absorption efficiency of the photo detectors 1003a, 1003b, 1003c is shown. The absorption efficiency of the photo detection device 1003 becomes an average value of the respective absorption efficiencies of light of the photo detectors 1003a, 1003b, 1003c. The absorption efficiency of the photo detection device 1003 has small wavelength dependency of light.

FIG. 4B is different from FIG. 4A in that a thickness of the semiconductor layer 5a of the photo detector 1003a, a thickness of the semiconductor layer 5b of the photo detector 1003b, and a thickness of the semiconductor layer 5c of the photo detector 1003c are changed from the respective thicknesses in the case of FIG. 4A.

FIG. 4B is calculated by simulation. The condition of simulation was that the substrate 90 is made of glass of a thickness of 0.3 mm, each of the semiconductor layers 5a, 5b, 5c is made of Si (silicon), each of the reflective materials 21a, 21b, 21c is made of Al (aluminum) of a thickness of 150 nm.

A thickness of each of the depletion layers 71a, 71b, 71c is 2 μm. The depletion layers 71a, 71b, 71c respectively exist in the semiconductor layers 5a, 5b, 5c which are 0.5 μm-2.5 μm distant from the substrate 90.

A thickness of the semiconductor layer 5a of the photo detector 1003a is 7.7 μm, a thickness of the semiconductor layer 5b of the photo detector 1003b is 7.742 μm, and a thickness of the semiconductor layer 5c of the photo detector 1003c is 7.786 μm.

In FIG. 4B, a light absorption efficiency of the photo detector 1003a, a light absorption efficiency of the photo detector 1003b, and a light absorption efficiency of the photo detector 1003c are respectively shown.

Each of the light absorption efficiency of the photo detector 1003a, the light absorption efficiency of the photo detector 1003b, and the light absorption efficiency of the photo detector 1003c depends on a wavelength of light. Each of the light absorption efficiency of the photo detector 1003a, the light absorption efficiency of the photo detector 1003b, and the light absorption efficiency of the photo detector 1003c largely depends on a wavelength of light, in the same manner as FIG. 4A.

Further, in FIG. 4B, an average light absorption efficiency of the photo detectors 1003a, 1003b, 1003c is shown. The absorption efficiency of the photo detection device 1003 becomes an average value of the respective absorption efficiencies of the photo detectors 1003a, 1003b, 1003c. The absorption efficiency of the photo detection device 1003 has a small wavelength dependency of light.

FIG. 4C shows the relation between a thickness of the semiconductor layer 5a of the photo detector 1003a and a light absorption efficiency of the photo detector 1003a. FIG. 4C is calculated by simulation. The condition of simulation was that the substrate 90 is made of glass of a thickness of 0.3 mm, the semiconductor layer 5a is made of Si, the reflective material 21a is made of Al of a thickness of 150 nm. FIG. 4C shows an absorption efficiency of light with a wavelength of 905 nm. When a thickness of the semiconductor layer 5a is changed, the light absorption efficiency becomes a maximum value each time the thickness of the semiconductor layer 5a changes by about 130 nm.

In this manner, in the photo detector 1003a, each time a thickness of the semiconductor layer 5a changes by 130 nm, the light absorption efficiency changes periodically. In the case of the light with a wavelength of 905 nm, in also the photo detectors 1003b, 1003c, each time a thickness of each of the semiconductor layers 5b, 5c changes by 130 nm, the light absorption efficiency periodically changes in the same manner as the photo detector 1003a.

For the reason, in the case that a wavelength of the light is 905 nm, if the difference between a thickness of the semiconductor layer 5a of the photo detector 1003a and a thickness of the semiconductor layer 5b of the photo detector 1003b is adjusted within a range of a thickness difference of at least 130 nm, the absorption characteristics of light of the photo detector 1003a and the photo detector 1003b can be made different.

FIG. 4D shows a thickness difference of the semiconductor layer 5a when a light absorption efficiency periodically becomes a maximum value in a light with a wavelength of 750-1000 nm,

It is found that if a wavelength of light becomes a long wavelength, a thickness difference of the semiconductor layer 5a when the light absorption efficiency periodically becomes maximum value becomes large.

In the case that a wavelength of the light is 1000 nm, in the photo detector 1003a, the light absorption efficiency becomes a maximum value, each time a thickness of the semiconductor layer 5a changes by 140 nm. For the reason, in the case that a wavelength of the light is 1000 nm, if the difference between a thickness of the semiconductor layer 5a of the photo detector 1003a and a thickness of the semiconductor layer 5b of the photo detector 1003b is adjusted within a range of a thickness difference of at least 140 nm, the absorption characteristics of the photo detector 1003a and the photo detector 1003b can be made different.

Accordingly, if the difference between the thickness of the semiconductor layer 5a of the photo detector 1003a and the thickness of the semiconductor layer 5b of the photo detector 1003b is adjusted within a range of the thickness difference of 140 nm, the absorption characteristics of the photo detector 1003a and the photo detector 1003b can be made different, for the light with a wavelength of 750-1000 nm.

However, if a thickness difference between the semiconductor layer 5a and the semiconductor layer 5b is small, it is difficult to make the absorption characteristics thereof different, and accordingly, it is preferable that there is a thickness difference of at least not less than 10 nm. Accordingly, it is preferable that the difference between a thickness of the semiconductor layer 5a of the photo detector 1003a and a thickness of the semiconductor layer 5b of the photo detector 1003b is made not less than 10 nm and not more than 140 nm. In addition, behavior of the light absorption efficiency becomes one cycle, in the thickness difference of 140 nm, it is possible to make the absorption characteristics of the photo detector 1003a and the photo detector 1003b different by the thickness difference above this value. For example, the difference between a thickness of the semiconductor layer 5a and a thickness of the semiconductor layer 5b has only to be not less than 10 nm and not more than 10 μm. If the thickness difference is made excessively large, since the absorption loss of light outside the depletion layer might increase by the amount corresponding to the thickness, it is not preferable to make the thickness difference larger than 10 μm.

In the photo detection device 1003, a structure thereof has only to be created for each pixel unit, and accordingly it is possible to manufacture it easily without requiring fine processing.

### Second Embodiment

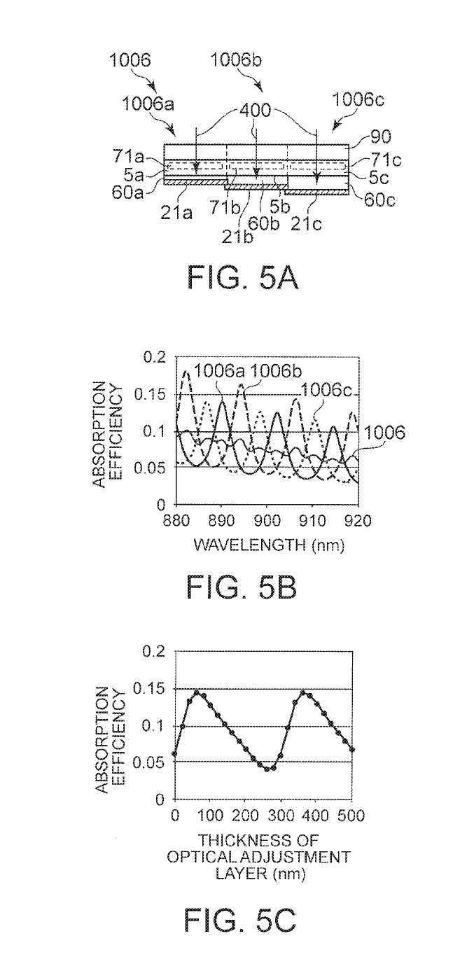

FIG. 5A is a diagram showing a photo detection device 1006, FIG. 5B is a diagram showing a light absorption efficiency of the photo detection device 1006, and FIG. 5C is a diagram showing the relation between light absorption efficiency of the photo detection device 1006 and a thickness of an optical property adjustment layer thereof are respectively shown.

In FIG. 5A, the photo detection device 1006 is further provided with optical property adjustment layers 60a, 60b, 60c in the photo detection device 1003. The same symbols are given to the same portions as in FIGS. 3A, 3B, 3C, and the description thereof will be omitted.

A photo detector (first photo detector) 1006a is composed of the substrate 90, the semiconductor layer (first semiconductor layer) 5a, the optical property adjustment layer 60a, and the reflective material (first reflective material) 21a. The substrate 90 is provided on the p⁺ type semiconductor layer 32 side of the semiconductor layer 5a. The p⁺ type semiconductor layer 32 of the semiconductor layer 5a forms a light receiving surface (first light receiving surface). The reflective material 21a is provided at a side opposite to the p⁺ type semiconductor layer 32 side of the semiconductor layer 5a. The depletion layer 71a exists inside the semiconductor layer 5a. The optical property adjustment layer (first optical property adjustment layer) 60a is provided between the semiconductor layer 5a and the reflective material 21a.

A photo detector (second photo detector) 1006b is composed of the substrate 90, the semiconductor layer (second semiconductor layer) 5b, the optical property adjustment layer 60b, and the reflective material (second reflective material) 21b. The substrate 90 is provided on the p⁺ type semiconductor layer 32 side of the semiconductor layer 5b. The p⁺ type semiconductor layer 32 of the semiconductor layer 5b forms a light receiving surface (second light receiving surface). The reflective material 21b is provided at a side opposite to the p⁺ type semiconductor layer 32 side of the semiconductor layer 5b. The depletion layer 71b exists inside the semiconductor layer 5b, The optical property adjustment layer (second optical property adjustment layer) 60b is provided between the semiconductor layer 5b and the reflective material 21b.

A photo detector 1006c is composed of the substrate 90, the semiconductor layer 5c, the optical property adjustment layer 60c, and the reflective material 21c. The substrate 90 is provided on the p⁺ type semiconductor layer 32 side of the semiconductor layer 5c. The reflective material 21c is provided at a side opposite to the p⁺ type semiconductor layer 32 side of the semiconductor layer 5c. The depletion layer 71c exists inside the semiconductor layer 5c. The optical property adjustment layer 60c is provided between the semiconductor layer 5c and the reflective material 21c.

The substrate 90 may be commonly used in the photo detector 1006a, the photo detector 1006b, and the photo detector 1006c.

The respective areas of the light receiving surface (first light receiving surface) of the photo detector 1006a, the light receiving surface (second light receiving surface) of the photo detector 1006b, the light receiving surface of the photo detector 1006c may be different from each other.

Between the substrate 90 and the semiconductor layer 5a, between the substrate 90 and the semiconductor layer 5b, and between the substrate 90 and the semiconductor layer 5c, passivation layers or adhesive layers not shown may be provided, respectively. The passivation layer is provided for protecting each of the semiconductor layers 5a, 5b, 5c. The passivation layer is a silicon oxide film (SiO₂). The adhesive layer is provided for improving adhesiveness of the substrate 90 with each of the semiconductor layers 5a, 5b, 5c, or adhesiveness of the substrate 90 with the passivation layer.

In the photo detection device 1006, a thickness of the semiconductor layer 5a of the photo detector 1006a, a thickness of the semiconductor layer 5b of the photo detector 1006b, and a thickness of the semiconductor layer 5c of the photo detector 1006c are equal to each other.

A thickness of the optical property adjustment layer 60a of the photo detector 1006a, a thickness of the optical property adjustment layer 60b of the photo detector 1006b, and a thickness of the optical property adjustment layer 60c of the photo detector 1006c are different from each other.

The thickness of the optical property adjustment layer 60a of the photo detector 1006a, the thickness of the optical property adjustment layer 60b of the photo detector 1006b, and the thickness of the optical property adjustment layer 60c of the photo detector 1006c are different from each other, and thereby absorption efficiencies of light in the respective wavelengths of light of the photo detector 1006a, the photo detector 1006b, and the photo detector 1006c are also different. For the reason, the wavelength dependency of light of the light absorption efficiency of the photo detection device 1006 can be made small.

FIG. 5B is calculated by simulation. The condition of simulation was that the substrate 90 is made of glass of a thickness of 0.3 mm, each of the semiconductor layers 5a, 5b, 5c is made of Si (silicon) of a thickness of 8 μm, the reflective materials 21a, 21b, 21c are made of Al (aluminum) of a thickness of 150 nm.

A thickness of each of the depletion layers 71a, 71b, 71c is 2 μm. The depletion layers 71a, 71b, 71c respectively exist in the semiconductor layers 5a, 5b, 5c which are 0.5 μm-2.5 μm distant from the substrate 90.

A thickness of the optical property adjustment layer 60a of the photo detector 1006a is 0 nm, a thickness of the optical property adjustment layer 60b of the photo detector 1006b is 120 nm, and a thickness of the optical property adjustment layer 60c of the photo detector 1006c is 260 nm. Refractive indexes of the optical property adjustment layers 60a, 60b, 60c are 1.5, respectively.

In FIG. 5B, a light absorption efficiency of the photo detector 1006a, a light absorption efficiency of the photo detector 1006b, and a light absorption efficiency of the photo detector 1006c are respectively shown.

Each of the light absorption efficiency of the photo detector 1006a, the light absorption efficiency of the photo detector 1006b, and the light absorption efficiency of the photo detector 1006c depends on a wavelength of light.

Further, in FIG. 5B, an average light absorption efficiency of the photo detectors 1006a, 1006b, 1006c is shown. The absorption efficiency of the photo detection device 1006 becomes an average value of the respective absorption efficiencies of light of the photo detectors 1006a, 1006b, 1006c. The absorption efficiency of the photo detection device 1006 has small wavelength dependency of light.

FIG. 5C shows the relation between a thickness of the optical property adjustment layer 60a of the photo detector 1006a and a light absorption efficiency of the photo detector 1006a. FIG. 5C is calculated by simulation. The condition of simulation was that the substrate 90 is made of glass of a thickness of 0.3 mm, the semiconductor layer 5a is made of Si of a thickness of 8 μm, the reflective material 21a is made of Al of a thickness of 150 nm. A refractive index of the optical property adjustment layer 60a is 1.5. FIG. 5C shows an absorption efficiency of light with a wavelength of 905 nm. When a thickness of the optical property adjustment layer 60a is changed, the light absorption efficiency becomes a maximum value each time a thickness of the optical property adjustment layer 60a changes by about 300 nm. Each time a thickness of the optical property adjustment layer 60a changes by 300 nm, the light absorption efficiency of the photo detector 1006a changes periodically. When the optical property adjustment layers 60b, 60c are composed of the same material as the optical property adjustment layer 60a, each time a thickness of each of the optical property adjustment layers 60b, 60c changes by 300 nm, the light absorption efficiency of each of the photo detectors 1006b, 1006c periodically changes in the same manner as the photo detector 1006a.

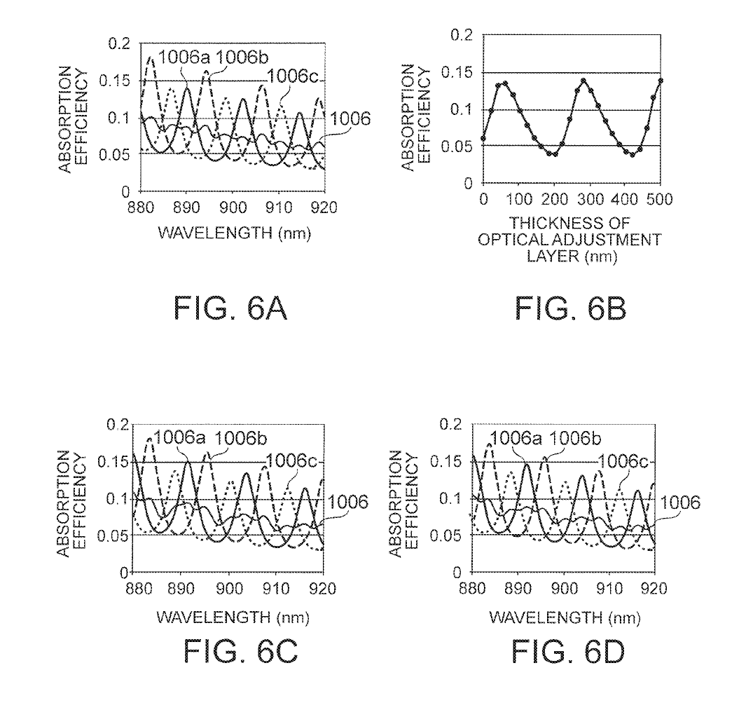

FIG. 6A is a diagram showing the relation between a light absorption efficiency and a wavelength of light in the photo detection device 1006, FIG. 6B is a diagram showing the relation between a light absorption efficiency of the photo detector 1006a and a thickness of the optical property adjustment layer 60a, FIG. 6C is a diagram showing the relation between a light absorption efficiency and a wavelength of light in the photo detection device 1006, and FIG. 6D is a diagram showing the relation between a light absorption efficiency and a wavelength of light in the photo detection device 1006.

FIG. 6A is calculated by simulation. The condition of simulation was that the substrate 90 is made of glass of a thickness of 0.3 mm, each of the semiconductor layers 5a, 5b, 5c is made of Si (silicon) of a thickness of 8 μm, each of the reflective materials 21a, 21b, 21c is made of Al (aluminum) of a thickness of 150 nm.

A thickness of each of the depletion layers 71a, 71b, 71c is 2 μm. The depletion layers 71a, 71b, 71c respectively exist in the semiconductor layers 5a, 5b, 5c which are 0.5 μm-2.5 μm distant from the substrate 90.

A thickness of the optical property adjustment layer 60a of the photo detector 1006a is 0 nm, a thickness of the optical property adjustment layer 60b of the photo detector 1006b is 80 nm, and a thickness of the optical property adjustment layer 60c of the photo detector 1006c is 180 nm. Refractive index of the optical property adjustment layers 60a, 60b, 60c are 2.0, respectively.

In FIG. 6A, a light absorption efficiency of the photo detector 1006a, a light absorption efficiency of the photo detector 1006b, and a light absorption efficiency of the photo detector 1006c are respectively shown.

Each of the light absorption efficiency of the photo detector 1006a, the light absorption efficiency of the photo detector 1006b, and the light absorption efficiency of the photo detector 1006c depends on a wavelength of light.

Further, in FIG. 6A, an average light absorption efficiency of the photo detectors 1006a, 1006b, 1006c is shown. The absorption efficiency of the photo detection device 1006 becomes an average value of the respective absorption efficiencies of the photo detectors 1006a, 1006b, 1006c. The absorption efficiency of the photo detection device 1006 has small wavelength dependency of light.

FIG. 6B shows the relation between a thickness of the optical property adjustment layer 60a of the photo detector 1006a and light absorption efficiency of the photo detector 1006a. FIG. 6B is calculated by simulation. The condition of simulation was that the substrate 90 is made of glass of a thickness of 0.3 mm, the semiconductor layer 5a is made of Si of a thickness of 8 μm, the reflective material 21a is made of Al of a thickness of 150 nm. A refractive index of the optical property adjustment layer 60a is 2.0. FIG. 6B shows an absorption efficiency of light with a wavelength of 905 nm. When a thickness of the optical property adjustment layer 60a is changed, the light absorption efficiency becomes a maximum value each time a thickness of the optical property adjustment layer 60a changes by about 220 nm. Each time a thickness of the optical property adjustment layer 60a changes by 220 nm, the light absorption efficiency of the photo detector 1006a changes periodically. When the optical property adjustment layers 60b, 60c are composed of the same material as the optical property adjustment layer 60a, each time a thickness of each of the optical property adjustment layers 60b, 60c changes by 220 nm, the light absorption efficiency of each of the photo detectors 1006b, 1006c periodically changes in the same manner as the photo detector 1006a.

In FIG. 6C, a light absorption efficiency of the photo detection device 1006 is shown. FIG. 6C is calculated by simulation. The condition of simulation was that the substrate 90 is made of glass of a thickness of 0.3 mm, each of the semiconductor layer 5a, 5b, 5c is made of Si (silicon) of a thickness of 8 μm, each of the reflective materials 21a, 21b, 21c is made of Al (aluminum) of a thickness of 150 nm.

A thickness of each of the depletion layers 71a, 71b, 71c is 2 μm. The depletion layers 71a, 71b, 71c respectively exist in the semiconductor layers 5a, 5b, 5c which are 0.5 μm-2.5 μm distant from the substrate 90.

A thickness of the optical property adjustment layer 60a of the photo detector 1006a is 20 nm, a thickness of the optical property adjustment layer 60b of the photo detector 1006b is 180 nm, and a thickness of the optical property adjustment layer 60c of the photo detector 1006c is 280 nm. Refractive indexes of the optical property adjustment layers 60a, 60b, 60c are 1.5, respectively.

Each of the light absorption efficiency of the photo detector 1006a, the light absorption efficiency of the photo detector 1006b, and the light absorption efficiency of the photo detector 1006c depends on a wavelength of light.

Further, in FIG. 6C, an average absorption efficiency of light of the photo detectors 1006a, 1006b, 1006c is shown. The absorption efficiency of the photo detection device 1006 becomes an average value of the absorption efficiencies of the photo detectors 1006a, 1006b, 1006c. The absorption efficiency of the photo detection device 1006 has small wavelength dependency of light.

In FIG. 6D, a light absorption efficiency of the photo detection device 1006 is shown. FIG. 6D is calculated by simulation. The condition of simulation was that the substrate 90 is made of glass of a thickness of 0.3 mm, each of the semiconductor layer 5a, 5b, 5c is made of Si (silicon) of a thickness of 8 Lm, each of the reflective materials 21a, 21b, 21c is made of Al (aluminum) of a thickness of 150 nm.

The thickness of each of the depletion layers 71a, 71b, 71c is 2 μm. The depletion layers 71a, 71b, 71c respectively exist in the semiconductor layers 5a, 5b, 5c which are 0.5 μm-2.5 μm distant from the substrate 90.

A thickness of the optical property adjustment layer 60a of the photo detector 1006a is 20 nm, a thickness of the optical property adjustment layer 60b of the photo detector 1006b is 120 nm, and a thickness of the optical property adjustment layer 60c of the photo detector 1006c is 200 nm. Refractive indexes of the optical property adjustment layers 60a, 60b, 60c are 2.0, respectively.

Each of the absorption efficiency of the photo detector 1006a, the light absorption efficiency of the photo detector 1006b, and the light absorption efficiency of the photo detector 1006c depends on the wavelength of light.

Further, in FIG. 6D, an average light absorption efficiency of the photo detectors 1006a, 1006b, 1006c is shown. The absorption efficiency of the photo detection device 1006 becomes an average value of the absorption efficiencies of the photo detectors 1006a, 1006b, 1006c. The absorption efficiency of the photo detection device 1006 has small wavelength dependency of light.

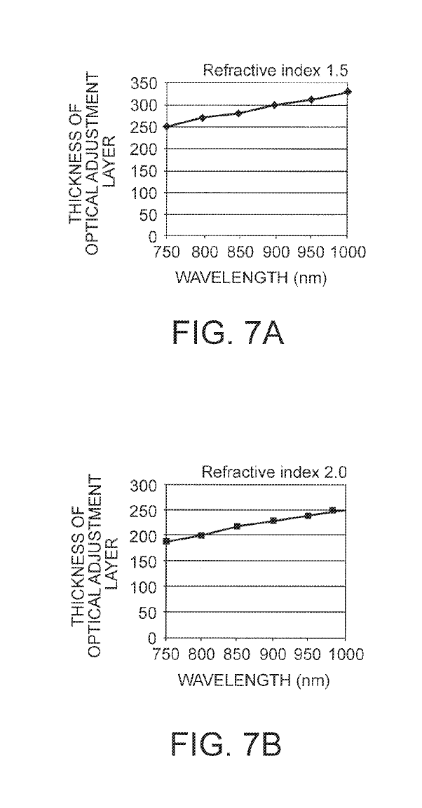

FIG. 7A is a diagram showing the relation between a thickness difference of the optical property adjustment layer and a wavelength of light in the case that a refractive index of the optical property adjustment layer is 1.5, and FIG. 7B is a diagram showing the relation between a thickness difference of the optical property adjustment layer and a wavelength of light in the case that a refractive index of the optical property adjustment layer is 2.0 are respectively shown.

FIG. 7A shows a thickness difference of the optical property adjustment layer 60a when a light absorption efficiency periodically becomes a maximum value in a light with a wavelength of 750-1000 nm.

It is found that if a wavelength of light becomes a long wavelength, a thickness difference of the optical property adjustment layer 60a when the light absorption efficiency periodically becomes a maximum value becomes large.

In the case that a wavelength of the light is 1000 nm, in the photo detector 1006a, the light absorption efficiency becomes a maximum value, each time a thickness of the optical property adjustment layer 60a changes by 330 nm. For the reason, in the case that a wavelength of the light is 1000 nm, if the difference between a thickness of the optical property adjustment layer 60a of the photo detector 1006a and a thickness of the optical property adjustment layer 60b of the photo detector 1006b is adjusted within a range of a thickness difference of at least 330 nm, the absorption characteristics of the photo detector 1006a and the photo detector 1006b can be made different.

Accordingly, if the difference between the thickness of the optical property adjustment layer 60a of the photo detector 1006a and the thickness of the optical property adjustment layer 60b of the photo detector 1006b is adjusted within a range of the thickness difference of 330 nm, the absorption characteristics of the photo detector 1006a and the photo detector 1006b can be made different, for the light with a wavelength of 750-1000 nm.

However, if a thickness difference between the optical property adjustment layer 60a and the optical property adjustment layer 60b is small, it is difficult to make the absorption characteristics thereof different, and accordingly, it is preferable that there is a thickness difference of at least not less than 10 nm. Accordingly, it is preferable that the difference between a thickness of the optical property adjustment layer 60a of the photo detector 1006a and a thickness of the optical property adjustment layer 60b of the photo detector 1006b is made not less than 10 nm and not more than 330 nm. In addition, behavior of the light absorption efficiency becomes one cycle, in the thickness difference of 330 nm, it is possible to make the absorption characteristics of the photo detector 1006a and the photo detector 1006b different by the thickness difference above this value. For example, the difference between a thickness of the optical property adjustment layer 60a and a thickness of the optical property adjustment layer 60b has only to be not less than 10 nm and not more than 10 μm. If the thickness difference is made excessively large, since the absorption loss of light outside the depletion layer might increase by the amount corresponding to the thickness, it is not preferable to make the thickness difference larger than 10 μm.

FIG. 7B shows a thickness difference of the optical property adjustment layer 60a when a light absorption efficiency periodically becomes a maximum value in a light with a wavelength of 750-1000 nm.

It is found that if a wavelength of light becomes a long wavelength, a thickness difference of the optical property adjustment layer 60a when the light absorption efficiency periodically becomes a maximum value becomes large.

In the case that a wavelength of the light is 1000 nm, in the photo detector 1006a, the light absorption efficiency becomes a maximum value, each time a thickness of the optical property adjustment layer 60a changes by 250 nm. For the reason, in the case that a wavelength of the light is 1000 nm, if the difference between a thickness of the optical property adjustment layer 60a of the photo detector 1006a and a thickness of the optical property adjustment layer 60b of the photo detector 1006b is adjusted within a range of a thickness difference of at least 250 nm, the absorption characteristics of the photo detector 1006a and the photo detector 1006b can be made different.

Accordingly, if the difference between the thickness of the optical property adjustment layer 60a of the photo detector 1006a and the thickness of the optical property adjustment layer 60b of the photo detector 1006b is adjusted within a range of the thickness difference of 250 nm, the absorption characteristics of the photo detector 1006a and the photo detector 1006b can be made different, for the light with a wavelength of 750-1000 nm.

However, if a thickness difference between the optical property adjustment layer 60a and the optical property adjustment layer 60b is small, it is difficult to make the absorption characteristics thereof different, and accordingly, it is preferable that there is a thickness difference of at least not less than 10 nm. Accordingly, it is preferable that the difference between a thickness of the optical property adjustment layer 60a of the photo detector 1006a and a thickness of the optical property adjustment layer 60b of the photo detector 1006b is made not less than 10 nm and not more than 250 nm. In addition, behavior of the light absorption efficiency becomes one cycle, in the thickness difference of 250 nm, it is possible to make the absorption characteristics of the photo detector 1006a and the photo detector 1006b different by the thickness difference above this value. For example, the difference between a thickness of the optical property adjustment layer 60a and a thickness of the optical property adjustment layer 60b has only to be not less than 10 nm and not more than 10 μm. If the thickness difference is made excessively large, since the absorption loss of light outside the depletion layer might increase by the amount corresponding to the thickness, it is not preferable to make the thickness difference larger than 10 μm.

### Third Embodiment

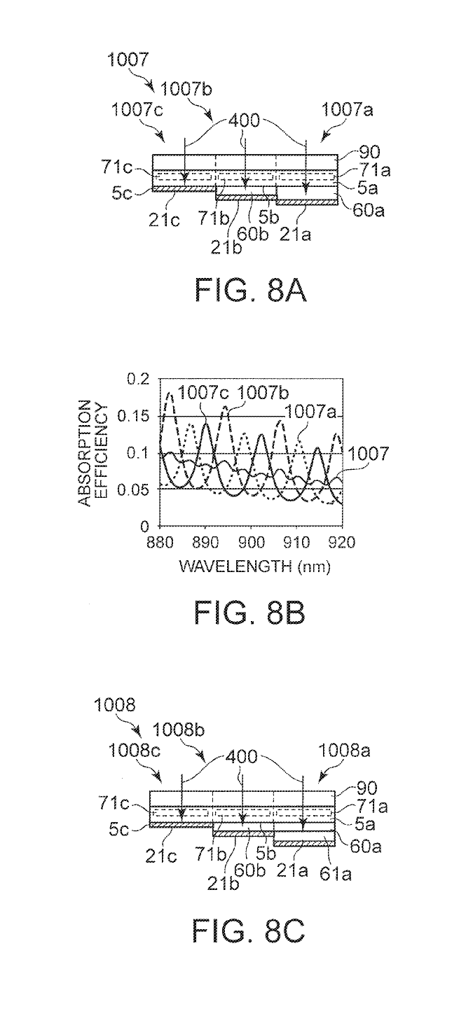

FIG. 8A is a diagram showing a photo detection device 1007, FIG. 8A is a diagram showing a light absorption efficiency of the photo detection device 1007, and FIG. 8C is a diagram showing a photo detection device 1008.

The same symbols are given to the same portions as in FIG. 5A, and the description thereof will be omitted.

In the photo detection device 1007 of FIG. 8A, the optical property adjustment layer 60a and the optical property adjustment layer 60b are respectively composed of different materials.

A photo detector (first photo detector) 1007a is composed of the substrate 90, the semiconductor layer (first semiconductor layer) 5a, the optical property adjustment layer (first optical property adjustment layer) 60a, and the reflective material (first reflective material) 21a. The p⁺ type semiconductor layer 32 of the semiconductor layer 5a forms a light receiving surface (first light receiving surface). The substrate 90 is provided on the p⁺ type semiconductor layer 32 side of the semiconductor layer 5a. The reflective material 21a is provided at a side opposite to the p⁺ type semiconductor layer 32 side of the semiconductor layer 5a. The depletion layer 71a exists inside the semiconductor layer 5a.

A photo detector (second photo detector) 1007b is composed of the substrate 90, the semiconductor layer (second semiconductor layer) 5b, the optical property adjustment layer (second optical property adjustment layer) 60b, and the reflective material (second reflective material) 21b. The p⁺ type semiconductor layer 32 of the semiconductor layer 5b forms a light receiving surface (second light receiving surface). The substrate 90 is provided on the p⁺ type semiconductor layer 32 side of the semiconductor layer 5b. The reflective material 21b is provided at a side opposite to the p⁺ type semiconductor layer 32 side of the semiconductor layer 5b. The depletion layer 71b exists inside the semiconductor layer 5b.

A photo detector 1007c is composed of the substrate 90, the semiconductor layer 5c, and the reflective material 21c. The type semiconductor layer 32 of the semiconductor layer 5c forms a light receiving surface. The substrate 90 is provided on the p⁺ type semiconductor layer 32 side of the semiconductor layer 5c. The reflective material 21c is provided at a side opposite to the p⁺ type semiconductor layer 32 of the semiconductor layer 5c. The depletion layer 71c exists inside the semiconductor layer 5c. In the photo detector 1007c, an optical property adjustment layer not shown may be provided between the semiconductor layer 5c and the reflective material 21c.

The substrate 90 may be commonly used in the photo detector 1007a, the photo detector 1007b, and the photo detector 1007c.

Between the substrate 90 and the semiconductor layer 5a, between the substrate 90 and the semiconductor layer 5b, and between the substrate 90 and the semiconductor layer 5c, passivation layers or adhesive layers not shown may be provided, respectively. The passivation layer is provided for protecting each of the semiconductor layers 5a, 5b, 5c. The passivation layer is a silicon oxide film (SiO₂). The adhesive layer is provided for improving adhesiveness of the substrate 90 with each of the semiconductor layers 5a, 5b, 5c, or adhesiveness of the substrate 90 with the passivation layer.

In the photo detection device 1007, a thickness of the semiconductor layer 5a of the photo detector 1007a, a thickness of the semiconductor layer 5b of the photo detector 1007b, and a thickness of the semiconductor layer 5c of the photo detector 1007c are equal to each other.

The optical property adjustment layer 60a is made of a material different from that of the optical property adjustment layer 60b. A refractive index of the optical property adjustment layer 60a is different from a refractive index of the optical property adjustment layer 60b.

A thickness of the optical property adjustment layer 60a of the photo detector 1007a, a thickness of the optical property adjustment layer 60b of the photo detector 1007b, and a thickness of the optical property adjustment layer 60c of the photo detector 1007c are different from each other.

For example, in FIG. 8A, the difference between a thickness of the optical property adjustment layer 60a of the photo detector 1007a and a thickness of the optical property adjustment layer 60b of the photo detector 1007b is preferably not less than 10 nm and not more than 10 ppm. It is more preferable that the difference between a thickness of the optical property adjustment layer 60a of the photo detector 1007a and a thickness of the optical property adjustment layer 60b of the photo detector 1007b is not less than 10 nm and not more than 300 nm.

FIG. 8B is calculated by simulation. The condition of simulation was that the substrate 90 is made of glass of a thickness of 0.3 mm, each of the semiconductor layers 5a, 5b, 5c is made of Si (silicon) of a thickness of 8 μm, each of the reflective materials 21a, 21b, 21c is made of Al (aluminum) of a thickness of 150 nm.

A thickness of each of the depletion layers 71a, 71b, 71c is 2 μm. The depletion layers 71a, 71b, 71c respectively exist in the semiconductor layers 5a, 5b, 5c which are 0.5 μm-2.5 μm distant from the substrate 90.

A thickness of the optical property adjustment layer 60a of the photo detector 1007a is 120 nm, and a thickness of the optical property adjustment layer 60b of the photo detector 1007b is 180 nm. A refractive index of the optical property adjustment layer 60a is 1.5. A refractive index of the optical property adjustment layer 60b is 2.0.

In FIG. 8B, absorption efficiencies of the photo detection device 1007 are respectively shown.

Each of the light absorption efficiency of the photo detector 1007a, the light absorption efficiency of the photo detector 1007b, and the light absorption efficiency of the photo detector 1007c depends on a wavelength of light.

Further, in FIG. 8B, an average light absorption efficiency of the photo detectors 1007a, 1007b, 1007c is shown. The absorption efficiency of the photo detection device 1007 becomes an average value of the respective absorption efficiencies of the photo detectors 1007a, 1007b, 1007c. The absorption efficiency of the photo detection device 1007 has small wavelength dependency of light.

The photo detection device 1008 is shown in FIG. 8C.

The same symbols are given to the same portions as in FIG. 5A, and the description thereof will be omitted.

In FIG. 8C, a photo detector (first photo detector) 1008a is composed of the substrate 90, the semiconductor layer (first semiconductor layer) 5a, optical property adjustment layers 60a, 61a, and the reflective material (first reflective material) 21a. The optical property adjustment layers 60a, 61a are collectively called a first optical property adjustment layer. The substrate 90 is provided on the p⁺ type semiconductor layer 32 side of the semiconductor layer 5a. The p⁺ type semiconductor layer 32 of the semiconductor layer 5a forms a light receiving surface (first light receiving surface). The reflective material 21a is provided at a side opposite to the p⁺ type semiconductor layer 32 side of the semiconductor layer 5a. The depletion layer 71a exists inside the semiconductor layer 5a.

A photo detector (second photo detector) 1008b is composed of the substrate 90, the semiconductor layer (second semiconductor layer) 5b, the optical property adjustment layer (second optical property adjustment layer) 60b, and the reflective material (second reflective material) 21b. The substrate 90 is provided on the p⁺ type semiconductor layer 32 side of the semiconductor layer 5b. The p⁺ type semiconductor layer 32 of the semiconductor layer 5b forms a light receiving surface (second light receiving surface). The reflective material 21b is provided at a side opposite to the p⁺ type semiconductor layer 32 side of the semiconductor layer 5b. The depletion layer 71b exists inside the semiconductor layer 5b.

A photo detector 1008c is composed of the substrate 90, the semiconductor layer 5c, and the reflective material 21c. The substrate 90 is provided on the p⁺ type semiconductor layer 32 side of the semiconductor layer 5c. The reflective material 21c is provided at a side opposite to the p⁺ type semiconductor layer 32 side of the semiconductor layer 5c. The depletion layer 71c exists inside the semiconductor layer 5c.

The substrate 90 may be commonly used in the photo detector 1008a, the photo detector 1008b, and the photo detector 1008c.

Between the substrate 90 and the semiconductor layer 5a, between the substrate 90 and the semiconductor layer 5b, and between the substrate 90 and the semiconductor layer 5c, passivation layers or adhesive layers not shown may be provided. The passivation layer is provided for protecting each the semiconductor layers 5a, 5b, 5c. The passivation layer is a silicon oxide film (SiO₂). The adhesive layer is provided for improving adhesiveness of the substrate 90 with each of the semiconductor layers 5a, 5b, 5c, or adhesiveness of the substrate 90 with the passivation layer.

In the photo detection device 1008, a thickness of the semiconductor layer 5a of the photo detector 1008a, a thickness of the semiconductor layer 5b of the photo detector 1008b, and a thickness of the semiconductor layer 5c of the photo detector 1008c are equal to each other.

The optical property adjustment layer 61a is made of a material different from those of the optical property adjustment layer 60a and the optical property adjustment layer 60b. That is, the first optical property adjustment layer is composed of a plurality of layers made of different materials, such as the optical property adjustment layers 60a, 61a of the photo detector 1008a. A refractive index of the optical property adjustment layer 61a is different from the refractive index of the optical property adjustment layer 60b and the refractive index of the optical property adjustment layer 60a. The light adjustment layer 61a is provided in the photo detector 1008a, and thereby it is possible to change the wavelength dependency of light of the photo detector 1008a.

### Fourth Embodiment

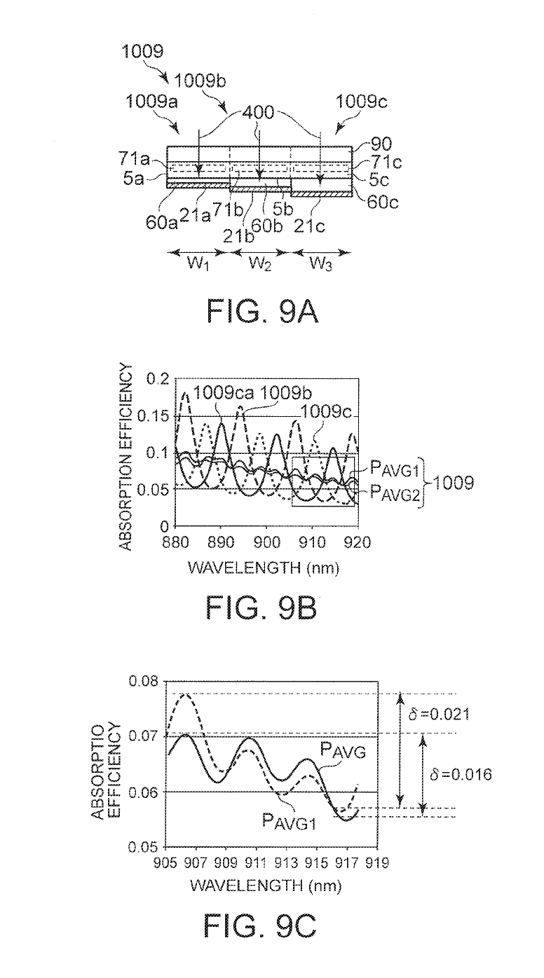

FIG. 9A is a diagram showing a photo detection device 1009, FIG. 9B is a diagram showing a light absorption efficiency of the photo detection device 1009, and FIG. 90 is an enlarged diagram of FIG. 9B.

The same symbols are given to the same portions as in FIG. 5A, and the description thereof will be omitted.

In FIG. 9A, a photo detector (first photo detector) 1009a is composed of the substrate 90, the semiconductor layer (first semiconductor layer) 5a, the optical property adjustment layer (first optical property adjustment layer) 60a, and the reflective material (first reflective material) 21a. The substrate 90 is provided on the p⁺ type semiconductor layer 32 side of the semiconductor layer 5a. The p⁺ type semiconductor layer 32 of the semiconductor layer 5a forms a light receiving surface (first light receiving surface). The reflective material 21a is provided at a side opposite to the p^{f} type semiconductor layer 32 side of the semiconductor layer 5a. The depletion layer 71a exists inside the semiconductor layer 5a.

A photo detector (second photo detector) 1009b is composed of the substrate 90, the semiconductor layer (second semiconductor layer) 5b, the optical property adjustment layer (second optical property adjustment layer) 60b, and the reflective material (second reflective material) 21b. The substrate 90 is provided on the p⁺ type semiconductor layer 32 side of the semiconductor layer 5b. The reflective material 21b is provided at a side opposite to the p⁺ type semiconductor layer 32 side of the semiconductor layer 5b. The p⁺ type semiconductor layer 32 of the semiconductor layer 5b forms a light receiving surface (second light receiving surface). The depletion layer 71b exists inside the semiconductor layer 5b.

A photo detector 1009c is composed of the substrate 90, the semiconductor layer 5c, the optical property adjustment layer 60c, and the reflective material 21c. The substrate 90 is provided on the p^{f} type semiconductor layer 32 side of the semiconductor layer 5c. The reflective material 21c is provided at a side opposite to the p⁺ type semiconductor layer 32 side of the semiconductor layer 5c. The depletion layer 71c exists inside the semiconductor layer 5c.

The substrate 90 may be commonly used in the photo detector 1009a, the photo detector 1009b, and the photo detector 1009c.

Between the substrate 90 and the semiconductor layer 5a, between the substrate 90 and the semiconductor layer 5b, and between the substrate 90 and the semiconductor layer 5c, passivation layers or adhesive layers not shown may be provided, respectively. The passivation layer is provided for protecting each of the semiconductor layers 5a, 5b, 5c. The passivation layer is a silicon oxide film (SiO₂), for example. The adhesive layer is provided for improving adhesiveness of the substrate 90 with each of the semiconductor layers 5a, 5b, 5c, or adhesiveness of the substrate 90 with the passivation layer.

In the photo detection device 1009, a thickness of the semiconductor layer 5a of the photo detector 1009a, a thickness of the semiconductor layer 5b of the photo detector 1009b, and a thickness of the semiconductor layer 5c of the photo detector 1009c are equal to each other.

In the photo detection device 1009, an area of the light receiving surface of the photo detector 1009a, an area of the light receiving surface of the photo detector 1009b, and an area of the light receiving surface of the photo detector 1009c are different from each other. It is decided that a length (width) of the photo detector 1009a is w₁, a length (width) of the photo detector 1009b is w₂, and a length (width) of the photo detector 1009c is w₃, in the horizontal direction.

FIG. 9B is calculated by simulation. The condition of simulation was that the substrate 90 is made of glass of a thickness 0.3 mm, each of the semiconductor layers 5a, 5b, 5c is made of Si (silicon) of a thickness 8 μm, each of the reflective materials 21a, 21b, 21c is made of Al (aluminum) of a thickness 150 nm.

A thickness of each of the depletion layers 71a, 71b, 71c is 2 μm. The depletion layers 71a, 71b, 71c respectively exist in the semiconductor layers 5a, 5b, 5c which are 0.5 μm-2.5 μm distant from the substrate 90.

A thickness of the optical property adjustment layer 60a of the photo detector 1009a is 0 nm, a thickness of the optical property adjustment layer 60b of the photo detector 1009b is 120 nm, and a thickness of the optical property adjustment layer 60c of the photo detector 1009c is 260 nm. Refractive indexes of the optical property adjustment layers 60a, 60b, 60c are 1.5, respectively.

In FIG. 9B, absorption efficiencies of the photo detection device 1009 are respectively shown.

Each of the light absorption efficiency of the photo detector 1009a, the light absorption efficiency of the photo detector 1009b, and the light absorption efficiency of the photo detector 1009c depends on a wavelength of light.

Further, in FIG. 9B, an average light absorption efficiency of the photo detectors 1009a, 1009b, 1009c is shown. The absorption efficiency of the photo detection device 1009 becomes an average value of the respective absorption efficiencies of the photo detectors 1009a, 1009b, 1009c. The absorption efficiency of the photo detection device 1009 has small wavelength dependency of light.

P_{AVG1} is a light absorption efficiency in a case that an area of the light receiving surface of the photo detector 1009a, an area of the light receiving surface of the photo detector 1009b, and an area of the light receiving surface of the photo detector 1009c are equal to each other. P_{AVG2} is a light absorption efficiency in a case that a ratio of an area of the light receiving surface of the photo detector 1009a, an area of the light receiving surface of the photo detector 1009b, and an area of the light receiving surface of the photo detector 1009c is 1.45:1:1.4.

FIG. 9C is a diagram in which a range from a wavelength of 905 nm to a wavelength of 918 nm in FIG. 9B is enlarged. In the photo detection device 1009, compared P_{AVG2} and P_{AVG1}, variation in the light absorption efficiency of the photo detection device 1009 due to wavelength change in the case of P_{AVG2} is smaller than that in the case of P_{AVG1}.

### Fifth Embodiment

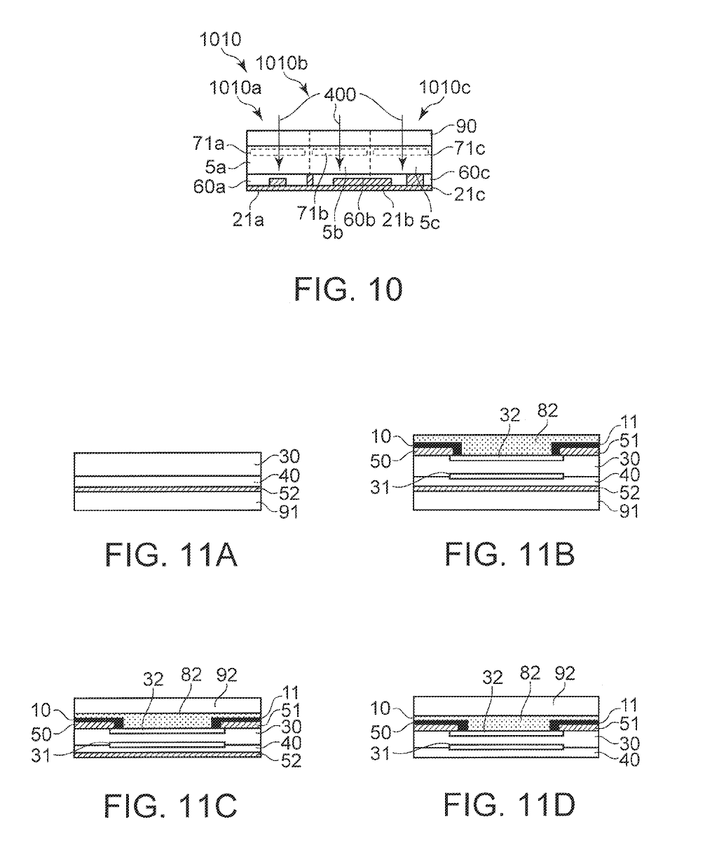

FIG. 10 is a diagram showing a photo detection device 1010.

The same symbols are given to the same portions as in FIG. 5A, and the description thereof will be omitted.

In FIG. 10, a photo detector (first photo detector) 1010a is composed of the substrate 90, the semiconductor layer (first semiconductor layer) 5a, the optical property adjustment layer (first optical property adjustment layer) 60a, and the reflective material (first reflective material) 21a. The substrate 90 is provided on the p⁺ type semiconductor layer 32 side of the semiconductor layer 5a. The p⁺ type semiconductor layer 32 of the semiconductor layer 5a forms a light receiving surface (first light receiving surface). The reflective material 21a is provided at a side opposite to the p⁺ type semiconductor layer 32 side of the semiconductor layer 5a. The depletion layer 71a exists inside the semiconductor layer 5a.

A photo detector (second photo detector) 1010b is composed of the substrate 90, the semiconductor layer (second semiconductor layer) 5b, the optical property adjustment layer (second optical property adjustment layer) 60b, and the reflective material (second reflective material) 21b. The substrate 90 is provided on the p⁺ type semiconductor layer 32 side of the semiconductor layer 5b. The p⁺ type semiconductor layer 32 of the semiconductor layer 5b forms a light receiving surface (second light receiving surface). The reflective material 21b is provided at a side opposite to the p⁺ type semiconductor layer 32 side of the semiconductor layer 5b. The depletion layer 71b exists inside the semiconductor layer 5b.

A photo detector 1010c is composed of the substrate 90, the semiconductor layer 5c, the optical property adjustment layer 60c, and the reflective material 21c. The substrate 90 is provided on the p⁺ type semiconductor layer 32 side of the semiconductor layer 5c. The reflective material 21c is provided at a side opposite to the p⁺ type semiconductor layer 32 side of the semiconductor layer 5c. The depletion layer 71c exists inside the semiconductor layer 5c.

The substrate 90 may be commonly used in the photo detector 1010a, the photo detector 1010b, and the photo detector 1010c.

Between the substrate 90 and the semiconductor layer 5a, between the substrate 90 and the semiconductor layer 5b, and between the substrate 90 and the semiconductor layer 5c, passivation layers or adhesive layers not shown may be provided, respectively. The passivation layer is provided for protecting each of the semiconductor layers 5a, 5b, 5c. The passivation layer is a silicon oxide film (SiO₂), for example. The adhesive layer is provided for improving adhesiveness of the substrate 90 with each of the semiconductor layers 5a, 5b, 5c, or adhesiveness of the substrate 90 with the passivation layer.

In the photo detection device 1010, a thickness of the semiconductor layer 5a in the photo detector 1010a, a thickness of the semiconductor layer 5b in the photo detector 1010b, and a thickness of the semiconductor layer 5c in the photo detector 1010c are equal to each other.

Each of the optical property adjustment layers 60a, 60b, 60c is a silicon oxide film or a silicon nitride film, for example. Each of the optical property adjustment layers 60a, 60b, 60c has a concave/convex shape. Concave/convex surfaces of the optical property adjustment layers 60a, 60b, 60c are respectively covered with the reflective materials 21a, 21b, 21c.

Each of the optical property adjustment layers 60a, 60b, 60c may be formed by arranging metals in a dot shape, or may be made of a material to spontaneously form a structure thereof by self-organization material.

### Manufacturing Method

FIGS. 11A to 11D are diagrams each showing a manufacturing method of the photo detector 1003a.

To begin with, a SOI (Silicon On Insulator) substrate is prepared, as shown in FIG. 11A. The SOI substrate has a structure in which a silicon substrate 91, a BOX (buried oxide layer) 52, an active layer (n type semiconductor layer) 40 are laminated in this order. The p⁻ type semiconductor layer 30 is formed on the n type semiconductor layer 40 by epitaxial growth.

Next, as shown in FIG. 11B, impurities (boron, for example) are implanted into a part of the region of the p⁻ type semiconductor layer 30. By this means, the p⁺ type semiconductor layer 31 composing a photo detection element is formed on a portion of the active layer 40 of the SOI substrate.

In addition, a first mask not shown is formed on the p⁻ type semiconductor layer 30, and p type impurities are implanted using this first mask, to form the p⁺ type semiconductor layer 32 serving as a photo detection region, on the p⁻ type semiconductor layer 30. After the above-described first mask is removed, a second mask not shown is formed on the p⁺ type semiconductor layer 32. The insulating layers 50, 51 are formed on the p⁻ semiconductor layer 30 using this second mask, and the first electrodes 10, 11 are respectively formed so as to cover the insulating layers 50, 51 and peripheral portions of the p⁺ semiconductor layer 32. Metal such as Ag, Al, Au, Cu or an alloy thereof is used for the first electrodes 10, 11. After the first electrodes 10, 11 are formed, the second mask is removed, and a passivation layer 82 is formed so as to cover the first electrodes 10, 11, and a part of the p⁺ type semiconductor layer 32. The passivation layer 82 is formed of an oxide film or photoresist, for example.

As shown in FIG. 11C, a support substrate 92 is provided on the passivation layer 82. After the support substrate 92 is provided, the support substrate 91 is subjected to dry etching. In this dry etching, a reaction gas such as SF₆ can be used, for example. When a reaction gas having etch selectivity of the silicon substrate 91 and the BOX 52 is used in this dry etching, the BOX 52 can be used as an etching stop film. In addition, when the silicon substrate 91 is sufficiently thick, a polishing process such as back grinding and CMP (Chemical Mechanical Polishing), or wet etching may be used together. When wet etching is used, KOH or TMAH (Tetra-Methyl-Ammonium Hydroxide) can be used as etchant. When the silicon substrate 91 is etched by means of this, the BOX 52 is exposed.

As shown in FIG. 11D, the exposed BOX 52 is removed by etching, and thereby a part of the n type semiconductor layer 40 is exposed. As this etching, wet etching with hydrofluoric acid or the like can be used. Wet etching like this is used, and thereby etch selectivity of the BOX 52 and silicon can be sufficiently ensured, and the exposed BOX 52 can be selectively removed.

In order to manufacture the photo detection device 1003, parts of a plurality of the n type semiconductor layers 40 in FIG. 11D are further etched, to change a total film thickness of the p⁻ type semiconductor layer 30 and the n type semiconductor layer 40. Combinations of the p⁻ type semiconductor layer 30 and the n type semiconductor layer 40 having different total film thicknesses are arrayed and connected. The quench resistor 200 may be provided so as to be connected to the first electrodes 10, 11, before the passivation layer 82 in FIG. 11B is provided, for example.

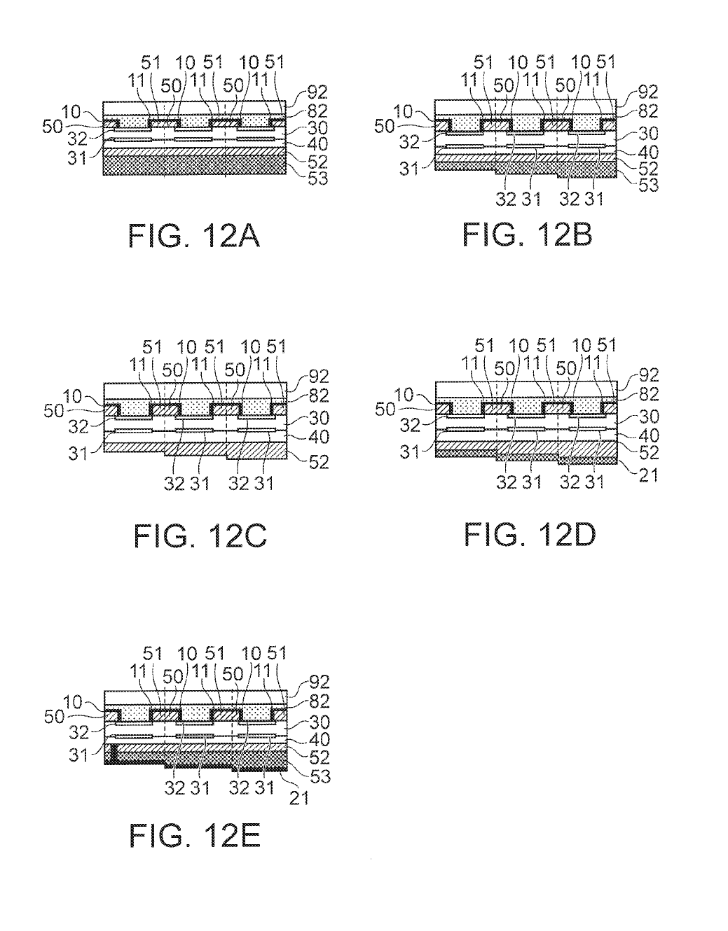

FIGS. 12A to 12E are diagrams each showing a manufacturing method of the photo detection device 1006.

In FIG. 12A, a plurality of the same members as the photo detector 1003a in FIG. 11C are aligned, and a film thickness control layer 53 is provided. The film thickness control layer 53 is an organic film formed of polymer, for example.

In FIG. 12B, a mold 100 described later is pressed to the film thickness control layer 53, to form the film thickness control layer 53 having different thicknesses.

In FIG. 12C, the film thickness control layer 53 and a part of the box 52 are etched using a wet process. At this time, the BOX 52 has thickness corresponding to the thickness of the film thickness control layer 53.

In FIG. 12D, after an opening is provided in a part of the BOX 52, the reflective material 21 is formed on the BOX 52. The opening is provided, to electrically connect the reflective material 21 and the semiconductor layer 40. The reflective material 21 can be used as an electrode.

In the process of FIG. 12C, the film thickness control layer has been etched with the wet process, but an opening is provided in the film thickness control layer 53 and a part of the BOX 52 in FIG. 12B, and then the reflective material 21 is formed, and thereby the photo detection device 1008 shown in FIG. 12E can be formed.

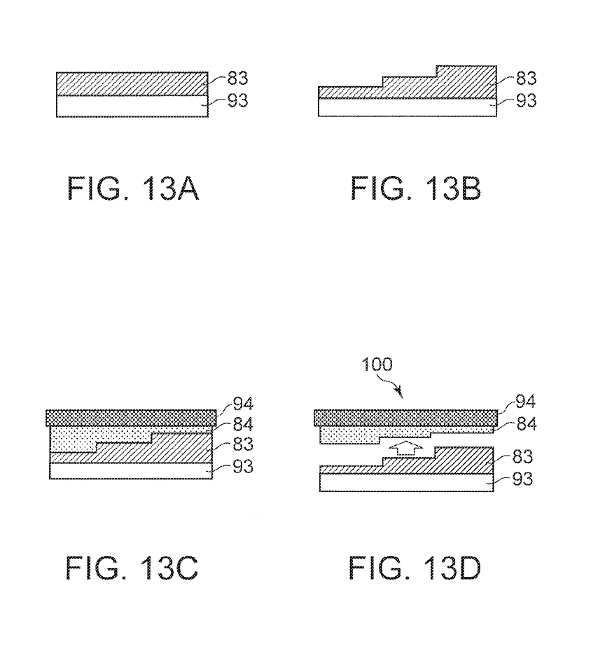

FIGS. 13A to 13D are diagram each showing a manufacturing method of the mold 100. In FIG. 13A, a mold forming layer 83 is provided on a substrate 93, in order to manufacture the mold 100.

In FIG. 13B, the mold forming layer 83 is irradiated with electron beam by an electron beam exposure device, for example, so that the depths of the respective regions thereof become different after etching. Further, a stepwise structure thereof is formed by wet etching.

In FIG. 13C, after a UV curing material 84 is formed on the stepwise mold forming layer 83, a substrate 94 is laminated thereon and they are subjected to exposure.

In FIG. 13D, the mold 100 composed of the substrate 94 and the UV curing material 84 is peeled from the mold forming layer 83.

### Sixth embodiment

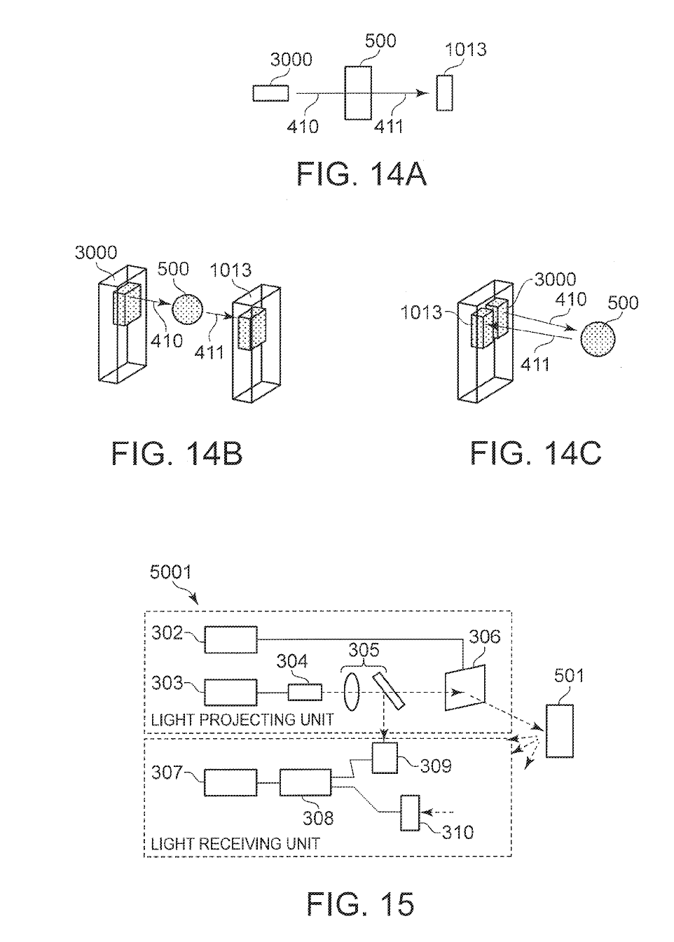

FIG. 14A is a diagram showing a measuring system, and FIGS. 14B, 14C are diagram showing specific examples of the measuring system.

The measuring system is composed of at least a photo detection device 1013 and a light source 3000. In the measuring system, the light source 3000 emits light 410 to a measuring object 500. The photo detection device 1013 detects light 411 which has passed through the measuring object 500 or has reflected or diffused from the measuring object 500. The measuring system may be configured such that the light source 3000 and the photo detection device 1013 are respectively housed in separate chassis, for example, as shown in FIG. 14B. Cr the light source 3000 and the photo detection device 1013 may be housed in the same chassis, as shown in FIG. 14C. Any of the photo detection devices 1003-1010 is used as the photo detection device 1013, and thereby it is possible to realize a measuring system in which a wavelength dependency is low, and which is less susceptible to wavelength variation of light that a photo detection device detects, such as wavelength variation of a light source.

### Seventh Embodiment

FIG. 15 is a diagram showing a LIDAR (Laser Imaging Detection and Ranging) device 5001.

The LIDAR device 5001 is provided with a light projecting unit and a light receiving unit.

The light projecting unit is composed of a light oscillator (light source) 304, a drive circuit 303, an optical system 305, a scan mirror 306, and a scan mirror controller 302. The light receiving unit is composed of a reference light detector 309, a photo detection device 310, a distance measuring circuit (measuring unit) 308, and an image recognition system 307.

In the light projecting unit, the laser light oscillator 304 oscillates laser light. The drive circuit 303 drives the laser light oscillator 304. The optical system 305 extracts a part of the laser light as reference light, and irradiates an object 501 with the other laser light via the mirror 306. The scan mirror controller 302 controls the scan mirror 306, to irradiate the object 501 with the laser light.

In the light receiving unit, the reference light detection device 309 detects the reference light extracted by the optical system 305. The photo detection device 310 receives the reflected light from the object 501. The distance measuring circuit 308 measures a distance to the object 501, based on the reference light detected by the reference light photo detection device 309 and the reflected light detected by the photo detection device 310. The image recognition system 307 recognizes the object 501 based on the result measured by the distance measuring circuit 308.

The LIDAR device 5001 is a distance image sensing system employing a light flight time ranging method (Time of Flight) which measures a time required for a laser light to reciprocate to a target, and converts the time into a distance. The LIDAR device 5001 is applied to an on-vehicle drive-assist system, remote sensing, and so on. If any of the photo detection devices 1003-1010 is used as the photo detection device 310, the LIDAR device 5001 expresses good sensitivity particularly in a near infra-red region. For this reason, it becomes possible to apply the LIDAR device 5001 to a light source in a human-invisible wavelength band. The LIDAR device 5001 can be used for obstacle detection for vehicle, for example.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photo detection device, comprising:
a first photo detector having a first semiconductor layer with a first light receiving surface;
a second photo detector having a second semiconductor layer with a second light receiving surface; and
a substrate which is arranged on the first light receiving surface of the first semiconductor layer and the second light receiving surface of the second semiconductor layer;
a thickness of the first semiconductor layer and a thickness of the second semiconductor layer being different from each other.

2. The photo detection device according to claim 1, wherein:
when a wavelength of the light is not less than 750 nm and not more than 1000 nm, a difference between the thickness of the first semiconductor layer and the thickness of the second semiconductor layer is not less than 10 nm and not more than 10 μm.

3. The photo detection device according to claim 2, wherein:
the difference between the thickness of the first semiconductor layer and the thickness of the second semiconductor layer is not less than 10 nm and not more than 140 nm.

4. The photo detection device according to claim 1, further comprising:
a first reflective material which is provided at a side opposite to the first light receiving surface of the first semiconductor layer, and reflects the light incident from the first light receiving surface of the first semiconductor layer.

5. The photo detection device according to claim 1, further comprising:
a second reflective material which is provided at a side opposite to the second light receiving surface of the second semiconductor layer, and reflects the light incident from the second light receiving surface of the second semiconductor layer.

6. A photo detection device, comprising:
a first photo detector having a first semiconductor layer with a first light receiving surface;
a second photo detector having a second semiconductor layer with a second light receiving surface;
a substrate which is arranged on the first light receiving surface of the first semiconductor layer and the second light receiving surface of the second semiconductor layer and transmits light;
a first reflective material which is provided at a side opposite to the first light receiving surface of the first semiconductor layer, and reflects the light incident from the first light receiving surface of the first semiconductor layer;
a second reflective material which is provided at a side opposite to the second light receiving surface of the second semiconductor layer, and reflects the light incident from the second light receiving surface of the second semiconductor layer;
a first optical property adjustment layer arranged between the first semiconductor layer and the first reflective material; and
a second optical property adjustment layer arranged between the second semiconductor layer and the second reflective material;
a thickness of the first optical property adjustment layer and a thickness of the second optical property adjustment layer being different from each other.

7. The photo detection device according to claim 6, wherein:
when a wavelength of the light is not less than 750 nm and not more than 1000 nm, a difference between the thickness of the first optical property adjustment layer and the thickness of the second optical property adjustment layer is not less than 10 nm and not more than 10 μm.

8. The photo detection device according to claim 7, wherein:
the difference between the thickness of the first optical property adjustment layer and the thickness of the second optical property adjustment layer is not less than 10 nm and not more than 330 nm.

9. The photo detection device according to claim 6, wherein:
the first optical property adjustment layer and the second optical property adjustment layer respectively include different materials from each other.

10. The photo detection device according to claim 6, wherein:
the first optical property adjustment layer includes a plurality of layers; and
the second optical property adjustment layer includes a plurality of layers.

11. The photo detection device according to claim 1, wherein:
the first photo detector includes a first quench resistor;
the second photo detector includes a second quench resistor; and
the first quench resistor and the second quench resistor are connected to each other.

12. The photo detection device according to claim 1, wherein:
the first semiconductor layer includes an n⁺ type semiconductor layer, an n⁻ type semiconductor layer, an n⁺ type semiconductor layer, and a p type semiconductor layer in this order from the first light receiving surface toward a direction opposite to the first light receiving surface side.

13. The photo detection device according to claim 1, wherein:
the first semiconductor layer includes a p⁺ type semiconductor layer, a p⁻ type semiconductor layer, a p⁺ type semiconductor layer, and an n type semiconductor layer in this order from the first light receiving surface toward a direction opposite to the first light receiving surface side.

14. The photo detection device according to claim 1, wherein:
the second semiconductor layer includes a p⁺ type semiconductor layer, a p type semiconductor layer, a p⁺ type semiconductor layer, and an n type semiconductor layer in this order from the second light receiving surface toward a direction opposite to the second light receiving surface side.

15. The photo detection device according to claim 1, wherein:
the second semiconductor layer includes an n⁺ type semiconductor layer, an n⁻ type semiconductor layer, an type semiconductor layer, and a p type semiconductor layer in this order from the second light receiving surface toward a direction opposite to the second light receiving surface side.

16. The photo detection device according to claim 1, wherein:
each of the first semiconductor layer and the second semiconductor layer includes Si.

17. The photo detection device according to claim 1, wherein:
an area of the first light receiving surface and an area of the second light receiving surface are different from each other.

18. A LIDAR device, comprising:
a light source to irradiate an object with light;
the photo detection device of claim 1 which detects the light reflected by the object; and
a measuring unit to measure a distance between the object and the photo detection device.
